(19) United States
(12) Patent Application Publication
(10) Pub. No.: US 2022/0037209 A1
(43) Pub. Date: Feb. 3, 2022

(54) METHOD FOR MANUFACTURING SEMICONDUCTOR STRUCTURE

(71) Applicants: Semiconductor Manufacturing International (Shanghai) Corporation, Shanghai (CN); Semiconductor Manufacturing International (Beijing) Corporation, Beijing (CN)

(72) Inventors: Jian CHEN, SHANGHAI (CN); Wutao TU, SHANGHAI (CN); Yan WANG, SHANGHAI (CN); Haiyang ZHANG, SHANGHAI (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 17/224,284

(22) Filed: Apr. 7, 2021

(30) Foreign Application Priority Data
Jul. 31, 2020 (CN) 202010762889.2

(51) Int. Cl. H01L 21/8234; H01L 21/762; H01L 21/3213; H01L 21/311; H01L 21/3065

(52) U.S. Cl. CPC H01L 21/823481; H01L 21/76224; H01L 21/823431; H01L 21/3065; H01L 21/32135; H01L 21/31116; H01L 21/823437

(57) ABSTRACT

One form of a method for manufacturing a semiconductor structure includes: providing a base, where the base includes a substrate and a plurality of discrete fins located on the substrate, a device region and an isolation region that are adjacent to each other, a metal gate structure formed on the substrate, where the metal gate structure spans the fins and covers parts of the tops and parts of side walls of the fins, an interlayer dielectric layer that is formed on the substrate exposed by the metal gate structure, where the interlayer dielectric layer covers a side wall of the metal gate structure; performing dry etching, where the metal gate structure in the isolation region and the fins located below the metal gate structure are sequentially etched to form an isolation trench surrounded by the interlayer dielectric layer and the remaining base; and forming an isolation structure in the isolation trench to simplify process steps of forming an isolation structure.

### RELATED APPLICATIONS

The present application claims priority to Chinese Patent Appln. No. 202010762889.2, filed Jul. 31, 2020, the entire disclosure of which is hereby incorporated by reference.

### BACKGROUND

### Technical Field

Embodiments and implementations of the present disclosure relate to the field of semiconductor manufacturing, and in particular, to a method for manufacturing a semiconductor structure.

### Related Art

In semiconductor manufacturing, with the development of very large scale integrated circuits, a feature size of the integrated circuits is continuously decreasing. To adapt to a smaller feature size, a channel length of a metal-oxide-semiconductor field-effect transistor (MOSFET) is also correspondingly reduced. However, as a channel length of a device becomes smaller, a distance between a source and a drain of the device correspondingly decreases. Therefore, a channel control capability of a gate structure deteriorates, and there is increased difficulty in pinching off the channel by a gate voltage, thereby resulting in an increase in a possibility of subthreshold leakage, that is, the so-called short-channel effect (SCE).

To better adapt to the reduced feature size, semiconductor processes have gradually transitioned from a planar MOSFET to a three-dimensional transistor with higher efficacy, for example, a fin field-effect transistor (FinFET). In the FinFET, a gate structure may control an ultra-thin body (a fin) from at least two sides, and compared with the planar MOSFET, the gate structure has a stronger channel control capability, and can suppress the short-channel effects well. Moreover, compared with other devices, the FinFET has better compatibility with manufacturing of the existing integrated circuits.

### SUMMARY

A problem to be addressed by embodiments and implementations of the present disclosure is to provide a method for manufacturing a semiconductor structure, to simplify process steps of forming an isolation trench.

To address the foregoing problem, one form of the present disclosure provides a method for manufacturing a semiconductor structure, including: providing a base, where the base includes a substrate and a plurality of discrete fins located on the substrate, the base includes a device region and an isolation region that are adjacent to each other, a metal gate structure is formed on the substrate, the metal gate structure spans the plurality of discrete fins and covers a portion of a top and a portion of side walls of the fins of the plurality of discrete finds, where an interlayer dielectric layer is formed on the substrate exposed by the metal gate structure, and the interlayer dielectric layer covers a side wall of the metal gate structure; performing dry etching, where the metal gate structure in the isolation region and the fins located below the metal gate structure are sequentially etched to form an isolation trench surrounded by the interlayer dielectric layer and the remaining base; and forming an isolation structure in the isolation trench.

In some implementations, the step of forming the interlayer dielectric layer and the metal gate structure includes: forming the interlayer dielectric layer on the base, where a gate opening spanning the plurality of discrete fins is formed in the interlayer dielectric layer; and forming the metal gate structure in the gate opening, where the metal gate structure includes a work function layer covering the bottom and side walls of the gate opening in a conformal manner and a gate electrode layer covering the work function layer and filled in the gate opening.

In some implementations, before the forming the metal gate structure in the gate opening, the method further includes: forming a high-k gate dielectric layer covering the bottom and the side walls of the gate opening in a conformal manner; and using the high-k gate dielectric layer as an etch-stop layer in the step of etching the metal gate structure in the isolation region; and the step of the dry etching further includes: etching the high-k gate dielectric layer located on the top of the substrate and the tops of the fins after the metal gate structure in the isolation region is etched, and before the fins are etched.

In some implementations, in the step of etching the metal gate structure in the isolation region, an etching selection ratio of the metal gate structure to the high-k gate dielectric layer is greater than 10:1.

In some implementations, before the metal gate structure in the isolation region is etched, the method further includes: forming a hard mask layer covering the interlayer dielectric layer and the metal gate structure; the step of the dry etching further includes: etching the hard mask layer in the isolation region to form a mask opening located above the metal gate structure before the metal gate structure in the isolation region is etched; and in the step of forming the isolation trench, the metal gate structure and the fins located below the metal gate structure are sequentially etched along the mask opening by using the remaining hard mask layer as a mask.

In some implementations, the step of the dry etching further includes: etching a part of the thickness of the substrate after the plurality of discrete fins is etched.

In some implementations, a process of the dry etching is an anisotropic dry etching process.

In some implementations, in the step of etching the gate electrode layer and in the step of etching the metal gate structure in the isolation region, process parameters for etching the metal gate structure include: a bias power of from 400 W to 1000 W, an etching time of from 20 s to 200 s, and a bias voltage of from 0 V to 100 V.

In some implementations, in the step of etching the metal gate structure in the isolation region, an etching gas includes one or more of SF₆, CF₄, and NF₃.

In some implementations, in the step of etching the high-k gate dielectric layer located on the top of the substrate and the tops of the fins, an etching gas includes one or both of BCl₃ and Cl₂.

In some implementations, in the step of etching the high-k gate dielectric layer located on the top of the substrate and the tops of the fins, process parameters for an etching process include: a bias power of from 400 W to 1200 W, an etching time of from 10 s to 100 s, and a bias voltage of from 50 V to 300 V.

In some implementations, along an extending direction of the fins, the base includes the device region and the isolation region that are adjacent to each other. Compared with the prior art, technical solutions of the embodiments of the present disclosure have the following advantages:

In the solutions disclosed by embodiments and implementations of the present disclosure, dry etching is performed, where a metal gate structure in an isolation region and fins located below the metal gate structure are sequentially etched to form an isolation trench surrounded by an interlayer dielectric layer and remaining base. Compared with a solution of etching the metal gate structure first using a wet etching process and then etching the fins using a dry etching process, in embodiments and implementations of the present disclosure, performing etching using an all-in-one dry etching procedure, for example, sequentially performing etching in a same etching device, simplifies process steps of forming an isolation trench.

### BRIEF DESCRIPTION OF THE DRAWINGS

FIG. 1 to FIG. 4 are schematic structural diagrams corresponding to steps in a method for manufacturing a semiconductor structure; and

FIG. 5 to FIG. 15 are schematic structural diagrams corresponding to steps in one form of a method for manufacturing a semiconductor structure according to the present disclosure.

### DETAILED DESCRIPTION

Currently, process steps of forming an isolation trench in an isolation region need to be simplified. With reference to a method for manufacturing a semiconductor structure, reasons why the process steps need to be simplified are now analyzed. FIG. 1 to FIG. 4 are schematic structural diagrams corresponding to steps in a method for manufacturing a semiconductor structure.

Referring to FIG. 1, a base is provided, where the base includes a substrate 10 and a plurality of discrete fins 11 located on the substrate 10. The base includes a device region II and an isolation region I that are adjacent to each other, where a metal gate structure 14 is formed on the substrate, the metal gate structure 14 spans the fins 11 and covers parts of the tops and parts of side walls of the fins 11, a protection layer 19 is formed on the top of the metal gate structure 14, a spacer 13 is formed on side walls of the metal gate structure 14 and the protection layer 19, and an interlayer dielectric layer 12 is formed on the substrate 10 exposed by the metal gate structure 14, and covers a side wall of the spacer 13.

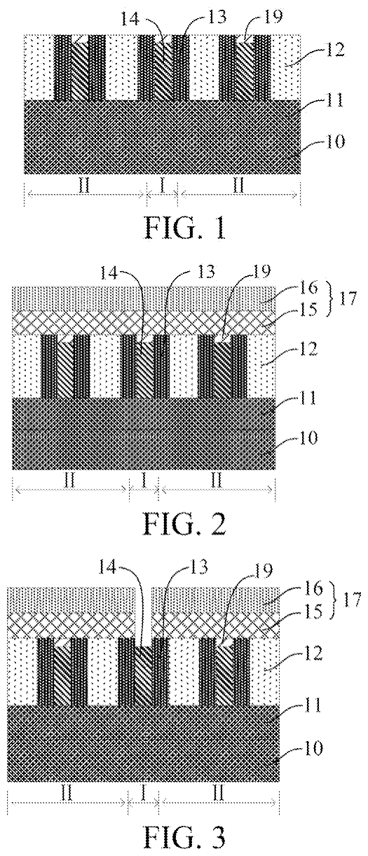

Referring to FIG. 2, a hard mask layer 17 is formed on the interlayer dielectric layer 12 and the spacer 13, and the hard mask layer 17 includes a nitride layer 15 and an oxide layer 16.

Referring to FIG. 3, in the isolation region I, the hard mask layer 17 and the protection layer 19 are dry-etched to expose the top of the metal gate structure 14.

Referring to FIG. 4, after the metal gate structure 14 is exposed, the metal gate structure 14 in the isolation region I are wet-etched.

Still referring to FIG. 4, the fins 11 and a part of the thickness of the substrate 10 in the isolation region I are dry-etched to form a single diffusion break isolation trench 18 surrounded by the spacer 13, the fins 11, and the substrate 10.

In the manufacturing method, the hard mask layer is first etched using a dry etching process, then, the metal gate structure is etched using a wet etching process, and further, the fins and the substrate are etched using a dry etching process. Foregoing steps need to be completed in different process machines. The process of forming the single diffusion break isolation trench 18 is excessively cumbersome.

To address the technical problem, implementations of the present disclosure provide a method for manufacturing a semiconductor structure, including: providing a base, where the base includes a substrate and a plurality of discrete fins located on the substrate, the base includes a device region and an isolation region that are adjacent to each other, a metal gate structure is formed on the substrate, the metal gate structure spans the fins and covers parts of the tops and parts of side walls of the fins, an interlayer dielectric layer is formed on the substrate exposed by the metal gate structure, and the interlayer dielectric layer covers a side wall of the metal gate structure; performing dry etching, where the metal gate structure in the isolation region and the fins located below the metal gate structure are sequentially etched to form an isolation trench surrounded by the interlayer dielectric layer and the remaining base; and forming an isolation structure in the isolation trench.

In solutions disclosed by implementations of the present disclosure, dry etching is performed, where a metal gate structure in an isolation region and fins located below the metal gate structure are sequentially etched to form an isolation trench surrounded by an interlayer dielectric layer and remaining bases. Compared with a solution of etching the metal gate structure first using a wet etching process and then etching the fins using a dry etching process, in implementations of the present disclosure, performing etching using an all-in-one dry etching procedure, for example, sequentially performing etching in a same etching device, simplifies process steps of forming an isolation trench.

To make the foregoing objectives, features, and advantages of embodiments and implementations of the present disclosure more apparent and easier to understand, specific embodiments and implementations of the present disclosure are described in detail below with reference to the drawings.

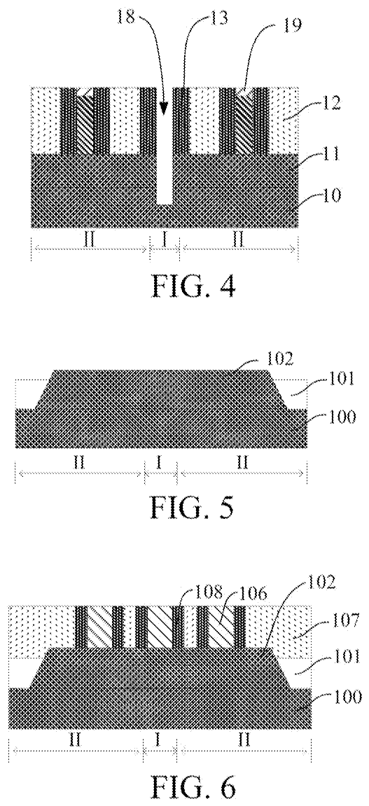

FIG. 5 to FIG. 15 are schematic structural diagrams corresponding to steps in one form of a method for manufacturing a semiconductor structure according to the present disclosure.

With reference to FIG. 5 to FIG. 9, a base is provided, where the base includes a substrate 100 and a plurality of discrete fins 102 located on the substrate 100. The base includes a device region II and an isolation region I that are adjacent to each other, a metal gate structure 117 is formed on the substrate 100, the metal gate structure 117 spans the fins 102 and covers parts of the tops and parts of side walls of the fins 102, an interlayer dielectric layer 107 is formed on the substrate exposed by the metal gate structure 117, and the interlayer dielectric layer 107 covers a side wall of the metal gate structure 117.

As shown in FIG. 5, in some implementations, the material of the substrate 100 is silicon. In some other implementations, the material of the substrate may alternatively be another material such as germanium, silicon germanide, silicon carbide, gallium arsenide, or indium gallide, and the substrate may alternatively be another type of base such as a silicon base on an insulator or a germanium base on an insulator.

In some implementations, the fins 102 are discretely provided on the substrate 100. The material of the fins 102 is the same as that of the substrate and t is silicon. In other implementations, the material of the substrate may alternatively be another material such as germanium, silicon carbide, gallium arsenide, or indium gallide, and the substrate 100 may alternatively be a silicon substrate on an insulator or a germanium substrate on an insulator.

The base includes a device region II and an isolation region I that are adjacent to each other. The device region II is configured to form a semiconductor device, the isolation region I is configured to form an isolation structure, and the isolation structure is configured to isolate adjacent devices.

In some implementations, along an extending direction of the fins 102, the base includes the device region II and the isolation region I that are adjacent to each other. The isolation structure subsequently formed in the isolation region I is configured to break the fins 102 in the extending direction of the fins 102, to serve as a single diffusion break (SDB) structure.

As shown in FIG. 5, in some implementations, the method for manufacturing a semiconductor structure further includes: after the fins 102 is formed, forming an isolating layer 101 on the substrate 100 exposed by the fin 102, where the isolating layer 101 covers parts of side walls of the fin 102.

The isolating layer 101 is configured to isolate adjacent devices. The material of the isolating layer 101 may be silicon oxide, silicon nitride, or silicon oxynitride. In some implementations, the material of the isolating layer 101 is silicon nitride.

In some implementations, the metal gate structure 117 is formed using a process of forming a high-k gate dielectric layer last or forming a gate electrode layer last (high k last/metal gate last). Therefore, before the metal gate structure 117 is formed, a process of forming a dummy gate is further included. The dummy gate is a spatial position occupied by the metal gate structure 117.

Specifically, referring to FIG. 6, a dummy gate 106 is formed on the substrate 100, and the dummy gate 106 spans the fins 102 and covers parts of the tops and parts of side walls of the fins 102.

In some implementations, the material of the dummy gate 106 is amorphous silicon. In some other implementations, the material of the dummy gate is polysilicon. In other implementations, the material of the dummy gate may alternatively be silicon oxide, silicon nitride, silicon oxynitride, silicon carbide, silicon carbonitride, silicon oxy-carbonitride, or amorphous carbon.

Still referring to FIG. 6, the interlayer dielectric layer 107 is formed on the substrate 100 exposed by the dummy gate 106, and the interlayer dielectric layer 107 covers a side wall of the dummy gate 106.

The interlayer dielectric layer 107 is configured to isolate the adjacent devices. The material of the interlayer dielectric layer 107 is an insulation material, for example, one or more of silicon oxide, silicon nitride, silicon oxynitride, silicon oxycarbide, silicon carbonitride, and silicon oxy-carbonitride. In some implementations, the material of the interlayer dielectric layer 107 is silicon nitride.

It should be noted that after the dummy gate 106 is formed, and before the interlayer dielectric layer 107 is formed, the method further includes: forming a spacer 108 on a side wall of the dummy gate 106; and after the spacer 108 is formed, forming a source/drain doped region in the fins 102 on two sides of the dummy gate 106.

The spacer 108 is configured to protect the side wall of the dummy gate 106. The spacer 108 may be a single-layer structure or a laminated structure. The material of the spacer 108 may be one or more of silicon oxide, silicon nitride, silicon carbide, silicon carbonitride, silicon oxy-carbonitride, silicon oxynitride, boron nitride, and boron carbonitride. In some implementations, the spacer 108 is of a single-layer structure, and the material of the spacer 108 is silicon nitride.

When a formed semiconductor device is a PMOS transistor, the material of the source/drain doped region is silicon germanide doped with P-type ions. The P-type ions include B, Ga, or In ions. When a formed semiconductor device is an NMOS transistor, the material of the source/drain doped region is silicon carbide or silicon phosphide doped with N-type ions. The N-type ions include P, As, or Sb ions.

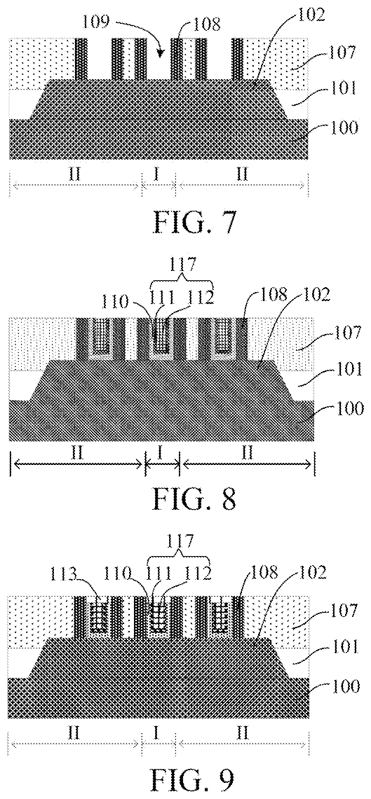

Referring to FIG. 7, after the interlayer dielectric layer 107 on the base 100 is formed, the dummy gate 106 in the isolation region I and the device region II is removed, and a gate opening 109 spanning the fins 102 is formed in the interlayer dielectric layer 107.

The gate opening 109 is configured to provide space for subsequent formation of a high-k gate dielectric layer and a metal gate structure. Referring to FIG. 8, a high-k gate dielectric layer 110 covering the bottom and side walls of the gate opening 109 in a conformal manner is formed.

A metal gate structure is formed in the remaining space of the gate opening 109 subsequently, and the metal gate structure in the isolation region I is further removed.

In the subsequent step of etching the metal gate structure in the isolation region I, the high-k gate dielectric layer 110 serves as an etch-stop layer.

Specifically, the material of the high-k gate dielectric layer 110 is a high-k dielectric material. The high-k dielectric material refers to a dielectric material having a relative dielectric constant greater than a relative dielectric constant of silicon oxide. In some implementations, the material of the high-k gate dielectric layer is HfO₂. In other implementations, the material of the high-k gate dielectric layer may alternatively be selected from ZrO₂, HfSiO, HfSiON, HfTaO, HfTiO, HfZrO or Al₂O₃.

Still referring to FIG. 8, after the high-k gate dielectric layer 110 is formed, the metal gate structure 117 is formed in the gate opening 109, the metal gate structure 117 includes a work function layer 111 covering the bottom and the side walls of the gate opening 109 in a conformal manner and a gate electrode layer 112 covering the work function layer 111 and filled in the gate opening 109.

The metal gate structure 117 serves as a device gate to control opening and closing of a channel of a transistor.

The work function layer 111 is configured to adjust a threshold voltage of the formed transistor. When the PMOS is formed, the work function layer 111 is a P-type work function layer. The material of the P-type work function layer is one or more of TiN, TaN, TaSiN, TaAIN, and TiAIN. When the NMOS is formed, the work function layer 111 is an N-type work function layer. The material of the N-type work function layer is one or more of TiAl, Mo, MoN, AlN, and TiAlC.

The gate electrode layer 112 is used for a subsequent electrical connection to an external structure. In some implementations, the material of the gate electrode layer 112 is one or both of TiAl and W.

In other implementations, the material of the gate electrode layer may alternatively be Al, Cu, Ag, Au, Pt, Ni, or Ti.

Referring to FIG. 9, the manufacturing method further includes: forming a protection layer 113 on the top of the metal gate structure 117 and the high-k gate dielectric layer.

The subsequent procedure further includes forming source/drain plugs in the interlayer dielectric layer 107 on two sides of the metal gate structure 117, the source/drain plug is electrically connected to the source/drain doped region, and a process of forming the source/drain plug includes a step of etching the interlayer dielectric layer 107 to form a contact hole and a step of filling the contact hole. In the step of etching the interlayer dielectric layer 107 to form the contact hole, the protection layer 113 can protect the metal gate structure 117 to prevent the metal gate structure 117 being exposed by the contact hole, thereby reducing the probability of a short circuit between the source/drain plug and the metal gate structure 117.

Particularly, when the contact is formed using a self-aligned contact (SAC) etching process, the spacer 108 is exposed in an etching process of forming the contact hole. The protection layer 113 located on the top of the metal gate structure 117 protects the metal gate structure 117, thereby enlarging a process window of the SAC etching process.

In some implementations, the step of forming the protection layer 113 includes: etching a part of the thickness of the metal gate structure 117 and a part of the thickness of the high-k gate dielectric layer 110 to form a groove; and filling the groove to form the protection layer 113. In some implementations, the material of the protection layer 113 is silicon nitride.

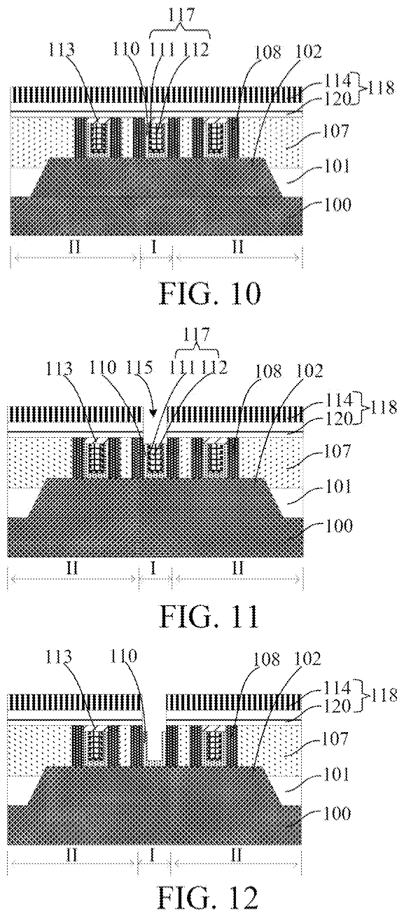

With reference to FIG. 10 to FIG. 14, dry etching is performed, where the metal gate structure 117 in the isolation region I and the fins 102 located below the metal gate structure 117 are sequentially etched to form an isolation trench 116 surrounded by the interlayer dielectric layer 107 and the remaining base.

The isolation trench 116 is configured to provide a spatial position for subsequent formation of an isolation structure.

Compared with a solution of etching the metal gate structure first using a wet etching process and then etching the fins using a dry etching process, in some implementations, performing etching using an all-in-one dry etching procedure, for example, sequentially performing etching in a same etching device, simplifies process steps of forming the isolation trench 116.

As shown in FIG. 10, before the metal gate structure 117 in the isolation region I is etched, the method further includes: forming a hard mask layer 118 covering the interlayer dielectric layer 107 and the metal gate structure 117.

The hard mask layer 118 of the isolation region I is subsequently etched. The etched hard mask layer 118 is used as a mask for forming an isolation trench by subsequently etching the metal gate structure 117 and the base.

In some implementations, the hard mask layer 118 is formed using a chemical vapor deposition (CVD) process.

In some implementations, the hard mask layer 118 includes a nitride layer 120 and an oxide layer 114.

Specifically, the material of the nitride layer 120 is silicon nitride (SiN), and the material of the oxide layer 114 is silicon oxide (SiO₂). In other implementations, the material of the hard mask layer may alternatively include one or more of TiN, SiN, and SiO₂.

As shown in FIG. 11, the hard mask layer 118 in the isolation region I is dry-etched to form a mask opening 115 located above the metal gate structure 117.

The mask opening 115 is located above the top of the to-be-etched metal gate structure 117.

In some implementations, the hard mask layer 118 in the isolation region I is etched using the dry etching process. The dry etching process has the property of anisotropic etching, so that a longitudinal etching rate of the dry etching process is much higher than a horizontal etching rate of the dry etching process, a very accurate graphic transformation can be obtained, and damage to side walls of the nitride layer 120 and the oxide layer 114 is relatively small.

Specifically, a process of the dry etching is an anisotropic dry etching process. In some implementations, the dry etching process is a plasma etching process.

The plasma refers to positive and negative charged ions and molecules generated after ionization of a gas. When being accelerated by an electric field, ionized gas atoms release sufficient power and surface expulsion forces to be tightly bound to a material or etch a surface.

In some implementations, the plasma etching process is characterized by simple operation, a relatively high etching rate, and the like, which help reduce the process complexity. In addition, an etching effect for the isolation region I is relatively prominent, and etching residues are unlikely to be left in the isolation region I.

In some implementations, the plasma etching process is an inductively coupled plasma etching process.

The inductively coupled plasma refers to a plasma source that generates a current as an energy source by changing an electromagnetic induction of a magnetic field with time. Low-temperature plasma is produced through an inductively coupled plasma etching process to etch a material surface.

It should be noted that after the hard mask layer 118 in the isolation region I is dry-etched to form the mask opening 115 located above the metal gate structure 117, and before the metal gate structure 117 in the isolation region I is dry-etched, the method for manufacturing a semiconductor structure further includes: dry etching the protection layer 113 on the top of the metal gate structure 117.

In some implementations, the material of the protection layer 113 is the same as the material of the nitride layer 120. Therefore, the nitride layer 120 and the protection layer 113 may be sequentially etched in a same etching step.

Referring to FIG. 12, the metal gate structure 117 is dry-etched along the mask opening 115 using the remaining hard mask layer 118 as a mask.

Specifically, the metal gate structure 117 is etched by the high-k gate dielectric layer 110 as an etch-stop layer. Using the high-k gate dielectric layer 110 as the etch-stop layer is conducive to ensuring that the metal gate structure 117 is completely removed.

In the device region II, source/drain doped regions are formed in the fins 102 on two sides of the metal gate structure 117. In the process of etching the metal gate structure 117, the high-k gate dielectric layer 110 can further protect the source/drain doped regions on two sides of the isolation region I to reduce the probability of damage to the source/drain doped regions.

In some implementations, a process of the dry etching is an anisotropic dry etching process.

For the anisotropic dry etching process, a longitudinal etching rate of the anisotropic dry etching process is much higher than a horizontal etching rate of the anisotropic dry etching process, a very accurate graphic transformation can be obtained, and the horizontal etching causes relatively small damage, so that damage to the side wall of the high-k gate dielectric layer 110 is correspondingly small.

In some implementations, the dry etching process is a plasma etching process. Specifically, the plasma etching process includes an inductively coupled plasma etching process.

In some implementations, an etching selection ratio of the metal gate structure to the high-k gate dielectric layer should not be too small. In the process of dry etching the metal gate structure 117, only the metal gate structure 117 needs to be removed, the high-k gate dielectric layer being used as the protection layer serving as the source/drain doped regions on the two sides of the isolation region I needs to be kept. Therefore, if the etching selection ratio is too small, the high-k gate dielectric layer is likely to be removed, resulting in damage to the source/drain doped regions on the two sides of the isolation region I. Therefore, in some implementations, the etching selection ratio of the metal gate structure to the high-k gate dielectric layer is greater than 10:1. The etching selection ratio refers to a ratio of an etching rate of the metal gate structure and to an etching rate of the high-k gate dielectric layer under dry etching process conditions. A high etching selection ratio means that the etching rate for a to-be-etched mask layer is much higher than the etching rate for another mask layer.

In some implementations, the etching power for etching the metal gate structure 117 should not be too large or too small. If the etching power is too large, damage is likely to be caused to the high-k gate dielectric layer 110. If the etching power is too small, the etching of the metal gate structure 117 is likely to be insufficient, possibly resulting in impact on the subsequent etching of the high-k gate dielectric layer 110, and impact on the performance of the transistor. Therefore, in some implementations, the bias power ranges from 400 W to 1000 W.

The etching time for etching the metal gate structure 117 should not be too long or too short. If the etching time is too long, damage is likely to be caused to the high-k gate dielectric layer 110. If the etching time is too short, the etching of the metal gate structure 117 is likely to be insufficient, possibly resulting in impact on the subsequent etching of the high-k gate dielectric layer 110 may be affected and impact on the performance of the transistor. Therefore, in some implementations, the etching time ranges from 20 s to 200 s.

The bias voltage for etching the metal gate structure 117 should not be too high or too low. If the bias voltage is too high, damage is likely to be caused to the high-k gate dielectric layer 110. If the bias voltage is too low, the etching of the metal gate structure 117 is likely to be insufficient, possibly resulting in impact on the subsequent etching of the high-k gate dielectric layer 110 and impact on the performance of the transistor. Therefore, in some implementations, the bias voltage ranges from 0 V to 100 V.

In some implementations, in the step of etching the metal gate structure 117 in the isolation region I, an etching gas includes one or more of SF₆, CF₄, and NF₃. The etching gas used for etching the gate electrode layer 112 may be the same as the etching gas used for etching the work function layer 111, thereby reducing the complexity of the etching process.

It should be noted that a fluorine-containing gas can be used not only for etching the work function layer 111, but also for etching the gate electrode layer 112. Therefore, the same etching gas can be used for etching the metal gate structure.

It should be noted that, in some implementations, it is easy for the fluorine-containing gas to etch the metal gate structure, but is difficult for the fluorine-containing gas to etch the high-k gate dielectric layer. Therefore, in the process of etching the metal gate structure 117 by using the fluorine-containing gas, it is not easy to etch the high-k gate dielectric layer 110, and an etching selection ratio of the metal gate structure to the high-k gate dielectric layer is relatively large, so that the high-k gate dielectric layer 110 can be used as the etch-stop layer.

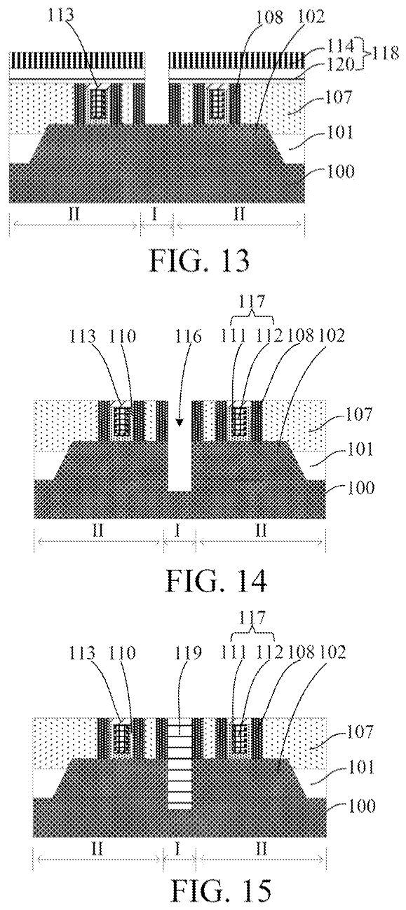

Referring to FIG. 13, after the metal gate structure 117 in the isolation region I is etched, and before the fins 102 is etched, the method further includes: etching the high-k gate dielectric layer 110 located on the top of the substrate 100 and the tops of the fins 102.

By etching the high-k gate dielectric layer 110 located on the top of the substrate 100 and the tops of the fins 102, the fins 102 are exposed for preparing for the subsequent etching of the fins 102.

In some implementations, in the step of etching the high-k gate dielectric layer 110 located on the top of the substrate 100 and the tops of the fins 102, the etching power for etching the high-k gate dielectric layer 110 should not be too large or too small. If the etching power is too large, damage is likely to be caused to the source/drain doped region on the two sides of the metal gate structure 117. If the etching power is too small, the etching of the high-k gate dielectric layer 110 is likely to be insufficient, resulting in impact on the subsequent etching of the substrate 100 and the fins 102, and impact on the performance of the transistor. Therefore, in some implementations, the etching power ranges from 400 W to 1200 W.

The etching time for etching the high-k gate dielectric layer 110 should not be too long or too short. If the etching time is too long, damage is likely to be caused to the source/drain doped regions on the two sides of the metal gate structure 117. If the etching time is too short, the etching of the high-k gate dielectric layer 110 is likely to be insufficient, and some residues are left, resulting in impact on the subsequent etching of the substrate 100 and the fins 102, and impact on the performance of the transistor. Therefore, in some implementations, the etching time ranges from 10 s to 100 s.

The bias voltage for etching the high-k gate dielectric layer 110 should not be too high or too low. If the bias voltage is too high, damage is likely to be caused to the source/drain doped regions on two sides of the metal gate structure 117. If the bias voltage is too low, the etching of the high-k gate dielectric layer 110 is likely to be insufficient, and some residues are left, resulting in impact on the subsequent etching of the substrate 100 and the fins 102, and impact on the performance of the transistor. Therefore, in some implementations, the bias voltage ranges from 50 V to 300 V.

In some implementations, in the step of etching the high-k gate dielectric layer located on the top of the substrate and the tops of the fins, an etching gas includes one or both of BCl₃ and Cl₂.

It is easy for a chlorine-containing gas to etch the high-k gate dielectric layer. In some implementations, the etching gas Cl₂ has relatively high efficiency of etching the high-k gate dielectric layer.

It should be noted that in the process of etching the high-k gate dielectric layer 110 located on the top of the substrate 100 and the tops of the fins 102, the high-k gate dielectric layer 110 located on the side wall of the gate opening 109 is likely to be etched and damaged.

As shown in FIG. 13, for example, after the high-k gate dielectric layer 110 located on the top of the substrate 100 and the tops of the fins 102 is etched, the high-k gate dielectric layer 110 located on the side wall of the gate opening 109 is also removed.

In other implementations, the high-k gate dielectric layer located on the side wall of the gate opening may also have residues. The material of the high-k gate dielectric layer is an insulation material, so that the electrical isolation effect of the adjacent device region II is not adversely affected.

Referring to FIG. 14, after the fins 102 is exposed, the fins 102 located below the metal gate structure 117 is continuously dry-etched to form an isolation trench 116 surrounded by the interlayer dielectric layer 107 and the remaining base.

Specifically, after the fins 102 are etched, a part of the thickness of the substrate 100 is also etched to increase the depth of the isolation trench 116, thereby improving the isolation effect of the subsequent isolation structure.

In other implementations, according to process requirements, only the fins may be etched, and the bottom of the isolation trench is correspondingly flush with the top of the substrate.

In some implementations, after the isolation trench 116 is formed, the method further includes: removing the hard mask layer 118. Referring to FIG. 15, an isolation structure 119 is formed in the isolation trench 116 (as shown in FIG. 14).

The isolation structure 119 is mainly configured to separate adjacent device regions II. The isolation structure 119 is a single diffusion break isolation structure.

The material of the isolation structure 119 is silicon oxide or silicon oxynitride. In some implementations, the material of the isolation structure 119 is silicon oxide.

In some implementations, the top surface of the isolation structure 119 is flush with the top surface of the interlayer dielectric layer 107.

Specifically, the isolation trench 116 is filled with an isolation material layer by using a flowable chemical vapor deposition (FCVD) process, and the isolation structure 119 in the isolation trench 116 is formed by performing planarization on the isolation material layer.

The FCVD process has a good gap filling capability, is conducive to reducing the probability of forming defects, such as voids, in the isolation material layer, and is correspondingly conducive to improving the isolation effect of the isolation structure 119.

In other implementations, a high aspect ratio-chemical vapor deposition process may alternatively be used to form the isolation material layer. The high aspect ratio chemical vapor deposition process can meet requirements of filling an opening with a high aspect ratio, so that the gap filling effect of the isolation material layer can be improved by using the high aspect ratio chemical vapor deposition process.

Although the present disclosure is disclosed above, the present disclosure is not limited thereto. A person skilled in the art may make various changes and modifications without departing from the spirit and scope of the present disclosure. Therefore, the protection scope of the present disclosure should be subject to the scope defined by the claims.

What is claimed is:

1. A method for manufacturing a semiconductor structure, comprising:
providing a base, wherein the base comprises:
a substrate and a plurality of discrete fins located on the substrate,
a device region and an isolation region that are adjacent to each other,
a metal gate structure formed on the substrate, where the metal gate structure spans the plurality of discrete fins and covers a part of a top and a part of a side wall of the fins of the plurality of discrete finds, and
an interlayer dielectric layer that is formed on the substrate exposed by the metal gate structure, where the interlayer dielectric layer covers a side wall of the metal gate structure;
performing dry etching, wherein the metal gate structure in the isolation region and the fins of the plurality of discrete fins located below the metal gate structure are sequentially etched to form an isolation trench surrounded by the interlayer dielectric layer and the remaining base; and
forming an isolation structure in the isolation trench.

2. The method for manufacturing a semiconductor structure according to claim 1, wherein the step of forming the interlayer dielectric layer and the metal gate structure comprises:
forming the interlayer dielectric layer on the base, wherein a gate opening spanning the plurality of discrete fins is formed in the interlayer dielectric layer; and
forming the metal gate structure in the gate opening, wherein the metal gate structure comprises a work function layer covering a bottom and side walls of the gate opening in a conformal manner and a gate electrode layer covers the work function layer and filled in the gate opening.

3. The method for manufacturing a semiconductor structure according to claim 2, wherein:
before forming the metal gate structure in the gate opening, the method further comprises:
forming a high-k gate dielectric layer covering the bottom and the side walls of the gate opening in a conformal manner; and
using the high-k gate dielectric layer as an etch-stop layer in the step of etching the metal gate structure in the isolation region; and
the step of the dry etching further comprises: etching the high-k gate dielectric layer located on the top of the substrate and the tops of the fins after the metal gate structure in the isolation region is etched, and before the fins are etched.

4. The method for manufacturing a semiconductor structure according to claim 3, wherein in the step of etching the metal gate structure in the isolation region, an etching selection ratio of the metal gate structure to the high-k gate dielectric layer is greater than 10:1.

5. The method for manufacturing a semiconductor structure according to claim 1, wherein:
before the metal gate structure in the isolation region is etched, the method further comprises: forming a hard mask layer covering the interlayer dielectric layer and the metal gate structure;
the step of the dry etching further comprises: etching the hard mask layer in the isolation region to form a mask opening located above the metal gate structure before the metal gate structure in the isolation region is etched; and
in the step of forming the isolation trench, the metal gate structure and the fins located below the metal gate structure are sequentially etched along the mask opening using the remaining hard mask layer as a mask.

6. The method for manufacturing a semiconductor structure according to claim 1, wherein the step of the dry etching further comprises: etching a part of the thickness of the substrate after the fins are etched.

7. The method for manufacturing a semiconductor structure according to claim 1, wherein a process of the dry etching is an anisotropic dry etching process.

8. The method for manufacturing a semiconductor structure according to claim 2, wherein in the step of etching the metal gate structure in the isolation region, process parameters for etching the metal gate structure comprise: a bias power of from 400 W to 1000 W, an etching time of from 20 s to 200 s, and a bias voltage of from 0 V to 100 V.

9. The method for manufacturing a semiconductor structure according to claim 2, wherein in the step of etching the metal gate structure in the isolation region, an etching gas comprises at least one of SF₆, CF₄, or NF₃.

10. The method for manufacturing a semiconductor structure according to claim 3, wherein in the step of etching the high-k gate dielectric layer located on the top of the substrate and the tops of the fins, an etching gas comprises at least one of BCl₃ or Cl₂.

11. The method for manufacturing a semiconductor structure according to claim 3, wherein in the step of etching the high-k gate dielectric layer located on the top of the substrate and the tops of the fins, process parameters for an etching process comprise: a bias power of from 400 W to 1200 W, an etching time of from 10 s to 100 s, and a bias voltage of from 50 V to 300 V.

12. The method for manufacturing a semiconductor structure according to claim 1, wherein along an extending direction of the plurality of discrete fins, the base comprises the device region and the isolation region that are adjacent to each other.
